(19) United States
(12) Patent Application Publication
(10) Pub. No.: US 2012/0177813 A1
(43) Pub. Date: Jul. 12, 2012

(54) CHEMICAL ANNEALING METHOD FOR FABRICATION OF ORGANIC THIN FILMS FOR OPTOELECTRONIC DEVICES

(76) Inventors: Mark E. Thompson, Anaheim, CA (US); Cong Trinh, Los Angeles, CA (US); Matthew T. Whited, Northfield, MN (US)

(21) Appl. No.: 13/274,875

(22) Filed: Oct. 17, 2011

Related U.S. Application Data
(60) Provisional application No. 61/393,921, filed on Oct. 17, 2010.

(51) Int. Cl. B05D 3/10; B05D 5/12; C23C 16/44

(52) U.S. Cl. 427/74; 427/337; 427/340

(57) ABSTRACT

There is disclosed a method of coordinating ligands, such as nitrogen-containing ligands to metal centers of metal-containing macrocyclic compounds, such as Magnesium Tetraphenyl Porphyrin (MgTPP) or Zinc Tetraphenyl Porphyrin (ZnTPP). The disclosed method comprises (a) forming an organic film comprising the disclosed metal-containing, macrocyclic compound; and (b) exposing the organic film to a vapor comprising at least one ligand for a time sufficient to coordinate the ligand to metal centers in the metal-containing, macrocyclic compound. There is also disclosed a method for preparing an organic photovoltaic device, such as a solar cell, comprising an ordered crystalline organic film made by the disclosed chemical annealing process.

### CROSS-REFERENCE TO RELATED APPLICATION

This application claims the benefit of U.S. Provisional Application No. 61/393,921, filed Oct. 17, 2010, which is incorporated herein by reference in its entirety.

### JOINT RESEARCH AGREEMENT

The subject matter of the present disclosure was made by, on behalf of, and/or in connection with one or more of the following parties to a joint university-corporation research agreement: The University of Southern California and Global Photonic Energy Corporation. The agreement was in effect on and before the date the subject matter of the present disclosure was prepared, and was made as a result of activities undertaken within the scope of the agreement.

### FIELD OF THE DISCLOSURE

The present disclosure generally relates to organic photosensitive optoelectronic devices and polaron pair recombination dynamics to impact efficiency and open circuit voltages of organic solar cells. The present disclosure also relates, in part, to methods of making organic photosensitive optoelectronic devices comprising the same.

There is disclosed a method of coordinating ligands, such as nitrogen-containing ligands to metal centers of metal-containing macrocyclic compounds, such as Zinc Tetraphenyl Porphyrin (ZnTPP). Upon coordination of ligands, the morphology of the film changes from amorphous to crystalline, especially when pyrazine (pyz) and triazine are used as ligands. Changing in film morphology has been observed by UV-vis spectroscopy, XRD and AFM measurements. Matching XRD patterns of the ZnTTP film treated with pyz and triazine with simulated diffraction patterns of ZnTPP.pyz and ZnTPP.triazine monocrystals clearly shows that highly ordered films was formed. Methods of making devices, and devices made by such methods are also disclosed.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements. As used herein the term “resistive load” refers to any power consuming or storing circuit, device, equipment or system.

Another type of photosensitive optoelectronic device is a photoconductor cell. In this function, signal detection circuitry monitors the resistance of the device to detect changes due to the absorption of light.

Another type of photosensitive optoelectronic device is a photodetector. In operation a photodetector is used in conjunction with a current detecting circuit which measures the current generated when the photodetector is exposed to electromagnetic radiation and may have an applied bias voltage. A detecting circuit as described herein is capable of providing a bias voltage to a photodetector and measuring the electronic response of the photodetector to electromagnetic radiation.

These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias. As a general rule, a photovoltaic cell provides power to a circuit, device or equipment, but does not provide a signal or current to control detection circuitry, or the output of information from the detection circuitry. In contrast, a photodetector or photoconductor provides a signal or current to control detection circuitry, or the output of information from the detection circuitry but does not provide power to the circuitry, device or equipment.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

PV devices may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%.

PV devices may be optimized for maximum electrical power generation under standard illumination conditions (i.e., Standard Test Conditions which are 1000 W/m², AM1.5 spectral illumination), for the maximum product of photocurrent times photovoltage. The power conversion efficiency of such a cell under standard illumination conditions depends on the following three parameters: (1) the current under zero bias, i.e., the short-circuit current I_{SC}, in Amperes (2) the photovoltage under open circuit conditions, i.e., the open circuit voltage V_{OC}, in Volts and (3) the fill factor, ff.

PV devices produce a photo-generated current when they are connected across a load and are irradiated by light. When irradiated under infinite load, a PV device generates its maximum possible voltage, V open-circuit, or V_{OC}. When irradiated with its electrical contacts shorted, a PV device generates its maximum possible current, I short-circuit, or I_{SC}. When actually used to generate power, a PV device is connected to a finite resistive load and the power output is given by the product of the current and voltage, I×V. The maximum total power generated by a PV device is inherently incapable of exceeding the product, I_{SC}×V_{OC}. When the load value is optimized for maximum power extraction, the current and voltage have the values, Iₘₐₓ and Vₘₐₓ, respectively.

A figure of merit for PV devices is the fill factor, ff, defined as:

ff={IₘₐₓVₘₐₓ}/{I_{SC}V_{OC}} (1)

where ff is always less than 1, as I_{SC} and V_{OC} are never obtained simultaneously in actual use. Nonetheless, as ff approaches 1, the device has less series or internal resistance and thus delivers a greater percentage of the product of I_{SC} and V_{OC} to the load under optimal conditions. Where P_{inc} is the power incident on a device, the power efficiency of the device, ηₚ, may be calculated by:

η_{P}=ff*(I_{sc}*V_{OC})/P_{inc}

To produce internally generated electric fields that occupy a substantial volume of the semiconductor, the usual method is to juxtapose two layers of material with appropriately selected conductive properties, especially with respect to their distribution of molecular quantum energy states. The interface of these two materials is called a photovoltaic junction. In traditional semiconductor theory, materials for forming PV junctions have been denoted as generally being of either n or p type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the conduction band minimum and valance band maximum energies. The Fermi energy characterizes the statistical occupation of molecular quantum energy states denoted by the value of energy for which the probability of occupation is equal to %. A Fermi energy near the conduction band minimum energy indicates that electrons are the predominant carrier. A Fermi energy near the valence band maximum energy indicates that holes are the predominant carrier. Accordingly, the Fermi energy is a primary characterizing property of traditional semiconductors and the prototypical PV junction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the junction between appropriately selected materials.

Production of crystalline film of molecular semiconductors with long range ordered architecture is desirable for organic electronic applications. There have been number of widely used physical methods to make highly ordered crystalline materials, such as solvent annealing and thermal annealing. In the solvent annealing method, organic films are exposed to vapors of solvents, which permeate into the films and impart enough conformational mobility to the molecules to relax them into the conformation with local minimal energy, and the treatment time can be minutes or days. Thermal annealing, in which structural change of thin films is induced by heating has been successfully employed in bulk heterojunction OPV. However, applying harsh condition is not desirable for devices using flexible plastic substrates or thermally unstable materials. It is noted that in both physical treatments, there is no change in chemical composition of the film.

There is disclosed herein a new chemical annealing method to change both chemical composition and morphology of macrocyclic complexes thin films. The method described herein relies on robust reaction of ligand vapors to the metal centers of macrocyclic compounds at mild conditions. The energy released from the associated chemical reaction can induce the change in morphology of the films. It is demonstrated herein that reactions of metal Tetraphenyl porphyrins (MTPP where M=Zn or Mg) thin film with various ligands (scheme 1) lead to this unexpected change in morphology. There is also disclosed a study on the effect of chemical annealing on organic photovoltaics (OPV) devices using ZnTPP film as the donor layer. Porphyrins were chosen because their rich properties with tunable electronic structures are suitable for many organic electronic, optoelectronic and gas sensor applications. This chemical annealing method can be expanded to large class of macrocyclic complexes which can potentially used in organic photovoltaic devices such as solar cells.

### SUMMARY

There is disclosed a method for preparing ordered crystalline organic films by chemical annealing, said method comprising:

(a) forming an organic film comprising at least one metal-containing, macrocyclic compound; and

(b) exposing the organic film to a vapor comprising at least one ligand for a time sufficient to coordinate said ligand to metal centers in the metal-containing, macrocyclic compound, thereby forming an ordered crystalline organic film.

There is also disclosed a method for preparing an organic photovoltaic device, such as a solar cell, comprising an ordered crystalline organic film, the method comprising:

(a) providing a first electrically conductive layer;

(b) depositing at least one donor material on the first electrically conductive layer, the donor layer comprising an organic film comprising at least one metal-containing, macrocyclic compound;

(c) exposing the organic film to a vapor comprising at least one ligand for a time sufficient to coordinate the ligand to metal centers in the metal-containing, macrocyclic compound, thereby forming an ordered crystalline organic film;

(d) depositing at least one acceptor material on the ordered crystalline organic film; and

(e) depositing a second electrically conductive layer on top of the acceptor material.

The foregoing and other features of the present disclosure will be more readily apparent from the following detailed description of exemplary embodiments, taken in conjunction with the attached drawings. It will be noted that for convenience all illustrations of devices show the height dimension exaggerated in relation to the width.

### BRIEF DESCRIPTION OF THE DRAWINGS

FIG. 1. are UV-vis spectra of 150 Å of ZnTPP film treated with various ligands over time.

FIG. 2. are UV-vis spectra of 150 Å of ZnTPP film under solvent vapors over time.

FIG. 3. are AFM images of ZnTPP films (100 \acute{Å}) on glass substrates treated with different ligands: a) ZnTPP, rms 6 \acute{Å}, vertical distance 32 \acute{Å} (in the section analysis); b) ZnTPP treated with triazine for 6 min, rms 21 \acute{Å}, vertical distance 104 \acute{Å}; ZnTPP-triazine 1 hr, rms 36 \acute{Å}, vertical distance 165 \acute{Å} d) ZnTPP-dmap 6 min, rms 5 \acute{Å}, vertical distance 28 \acute{Å}; e) ZnTPP-dmap 1 hr, rms 26 \acute{Å}, vertical distance 118 \acute{Å}; f) ZnTPP-pyCN 1 hr, rms 4 \acute{Å}, vertical distance 11 \acute{Å}; g) ZnTPP-Phimi 3 min, rms 5 \acute{Å}, vertical distance 23 \acute{Å}.

FIG. 4. are x-ray diffraction (XRD) patterns of the 1000 \acute{Å} ZnTPP films before and after chemical annealing with different ligands.

FIG. 5. are matching x-ray diffraction (XRD) patterns of 1000 \acute{Å} ZnTPP.ligand films with simulated patterns (columns) from monocrystal. a) XRD patterns of ZnTPP.pyz monocrystal (black columns) and ZnTPP ZnTPP.pyz film before and after heating at different temperature for one hour; b) XRD patterns of ZnTPP.pyz monocrystal (black columns) and ZnTPP ZnTPP.triazine film before and after heating at different temperature for one hour; c) Crystal structure and packing of ZnTPP.pyz; d) Crystal structure and packing of ZnTPP.trazine complex, the (202) planes which have d₂₀₂ spacing=4.702 \acute{Å} and corresponds to 2θ=18.8° are shown.

FIG. 6. are x-ray diffraction (XRD) patterns of ZnTPP films after a) Thermal annealing at different temperatures for one hour under N₂; b) Solvent (DCM) annealing for one hour. Simulated patterns from monoclinic (red columns) and triclinic (black columns) polymorphs of ZnTPP monocrystals are shown for comparison.

FIG. 7. are x-ray diffraction (XRD) patterns of thermally annealed ZnTPP films, then treated with pyz.

FIG. 8. are J-V curves of organic solar cell with structure: ITO/donor layer/C₆₀ (400 \acute{Å})/BCP (100 \acute{Å})/Al (1000 \acute{Å}), the donor layers were made in different ways: S1—ZnTPP (150 \acute{Å}), S2—ZnTPP (150 \acute{Å}) treated with pyz, S3—NPD (100 \acute{Å})/ZnTPP (150 \acute{Å})-pyz, S4—NPD (100 \acute{Å})/ZnTPP (150 \acute{Å})-pyz, S5—ZnTPP (100 \acute{Å})-pyz/ZnTPP (50 \acute{Å}), S6—ZnTPP (200 \acute{Å}), S7—ZnTPP (200 \acute{Å})-pyz and S8—ZnTPP (100 \acute{Å})-pyz/ZnTPP (100 \acute{Å}). a) under illumination, b) under dark condition.

FIG. 9. are UV-vis absorption spectra of 150 \acute{Å} film of MgTPP annealed with py, pyz, and organic solvents—DCM, Hexanes (hex).

FIG. 10. are x-ray diffraction (XRD) patterns of MgTPP film before and after chemical annealing with py and pyz, or solvent annealing with DCM and hexanes.

FIG. 11. are structures of porphyric monomers, porphyric oligomers, fused and confused porphyrins, phthalocyanine derivatives. X1-8 can be any π-extend systems. R₁₋₄ can be alkyl, aromatic or other functional substituents, Y₁ and Y₂ can be any atoms that are suitable for these structures.

FIG. 12. are general structures of macrocyclic compounds, examples are listed. X₁₋₄ can be any alkyl, aromatic systems. X₁₋₄ and Y₁₋₄ can be any atom that fit into these structures.

FIG. 13. are general structures of ligands. R₁₋₇ can be alkyl, aromatic or other functional substituents, X₁₋₁₃ can be any atoms that are suitable for these structures. A and E can be any element from groups VA and VIA of periodic table, respectively.

FIG. 14. a) Crystal structure of ZnTPP.pyz; b) Matching XRD patterns of ZnTPP-pyz thin film with simulated patterns from monocrystal diffraction of ZnTPP.pyz; c) Current density-Voltage curves of lamellar solar cells with donor layers as following: S1—ZnTPP (150 \acute{Å}), S2—ZnTPP.pyz (150), S3—NPD (100)/ZnTPP (150), S4—NPD (100 \acute{Å})/ZnTPP (150 \acute{Å})-pyz, S5—ZnTPP (100 \acute{Å})-pyz/ZnTPP (50 \acute{Å}).

FIG. 15. illustrates dark current under applied forward bias.

### DETAILED DESCRIPTION OF THE INVENTION

There is disclosed a new method—chemical annealing to convert amorphous films of metal containing macrocyclic compounds into crystalline films. In this chemical process, the thin films of macrocyclic complexes are exposed to vapors of ligands that can coordinate to the metal centers, converting the amorphous film into crystalline film.

As examples, the amorphous films of Zinc and Magnesium Tetraphenyl porphyrins (MTPP where M=Zn or Mg) have been exposed to vapors of various ligands: pyridine (py), 4-cyano pyridine (pyCN), 4-dimethylamino pyridine (dmap), triazine, pyrazine (pyz), imidazole (Himi), methyl imidazole (Meimi), phenyl imidazole (Phimi), diethylamine (Et₂N), triethylamine (Et₃N) and tetrahydrofuran (THF). Reaction of different ligands with ZnTPP film which could be observed visually or spectroscopically is reversible. Transformation of amorphous films of MTPP into crystalline films MTPP.ligands was confirmed by X-ray diffraction measurements.

The influence of changing film morphology on Organic Photovoltaics (OPV) devices using ZnTPP as a donor material is also disclosed. Crystalline donor film ZnTPP.pyz results in higher conductivity and low V_{OC} due to the increase of dark current Jₛ relative to the devices with a pure ZnTPP donor layer. The chemical annealing with different ligands can be applied to various macrocyclic compounds to achieve highly ordered films, which will help to improve conductivity of organic films. Thus, the chemical annealing approach is a useful way to fabricate crystalline films in organic electronic devices.

In one embodiment, the new chemical treatment method-chemical annealing to make highly ordered crystalline films of macrocyclic compounds has been demonstrated by MTPP films treated with different Lewis bases. In chemical annealing, metal containing macrocyclic compounds's films are exposed to ligands, which can coordinate to metal centers generating highly ordered crystalline films with new chemical composition. That approach can be widely used to make crystalline organic film used in organic electronic devices and/or sensor application.

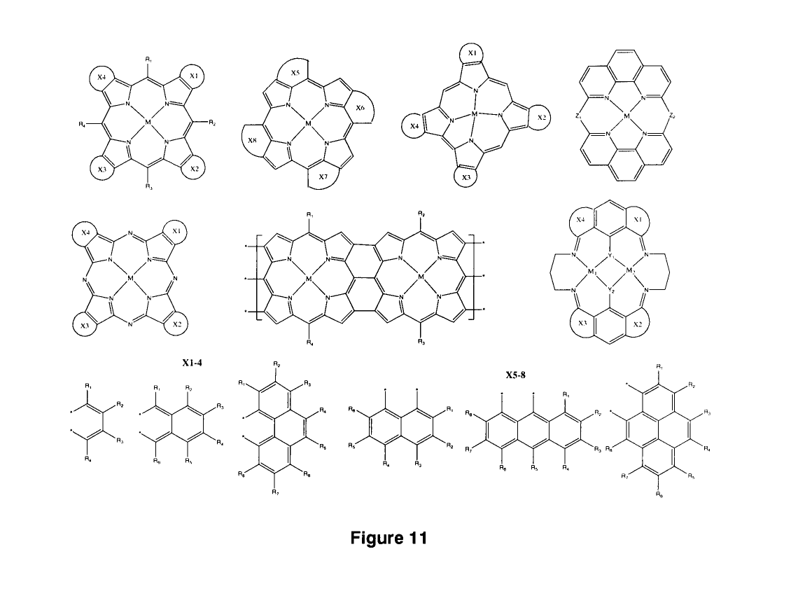

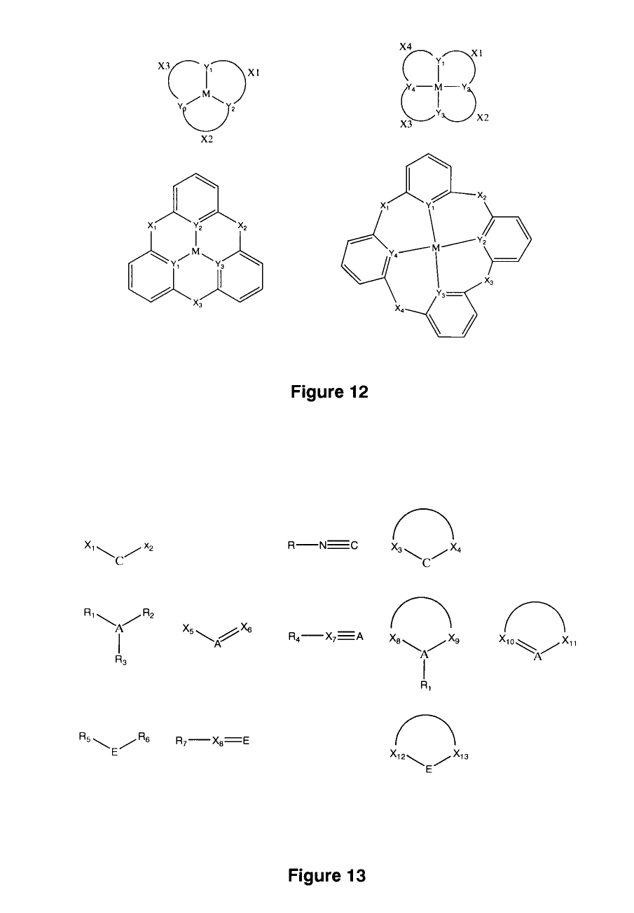

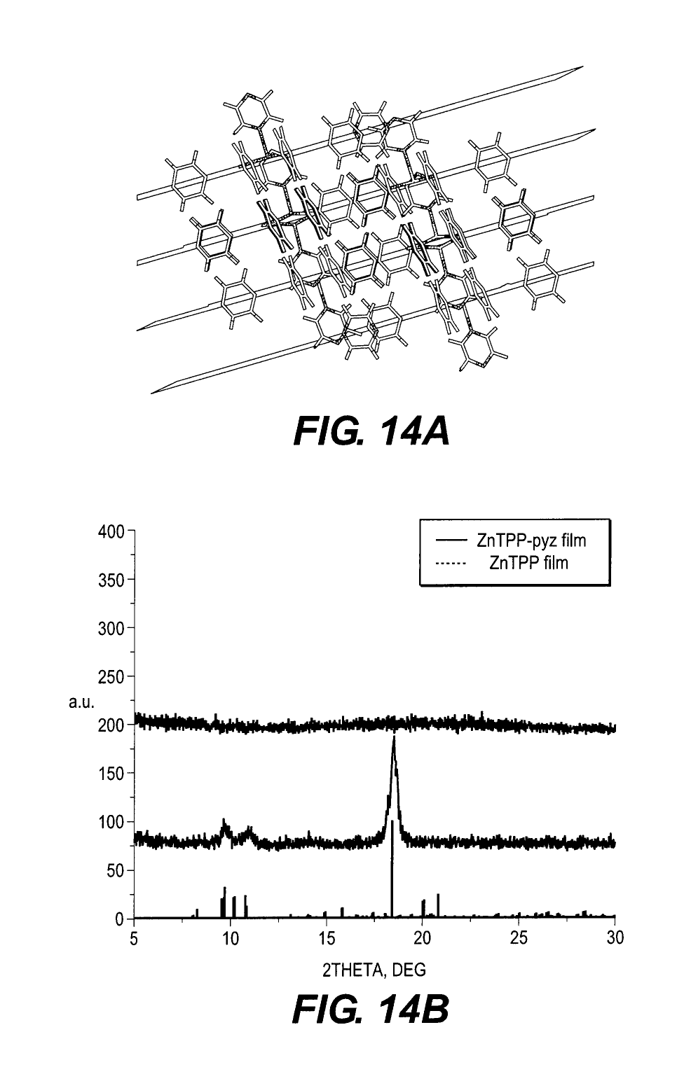

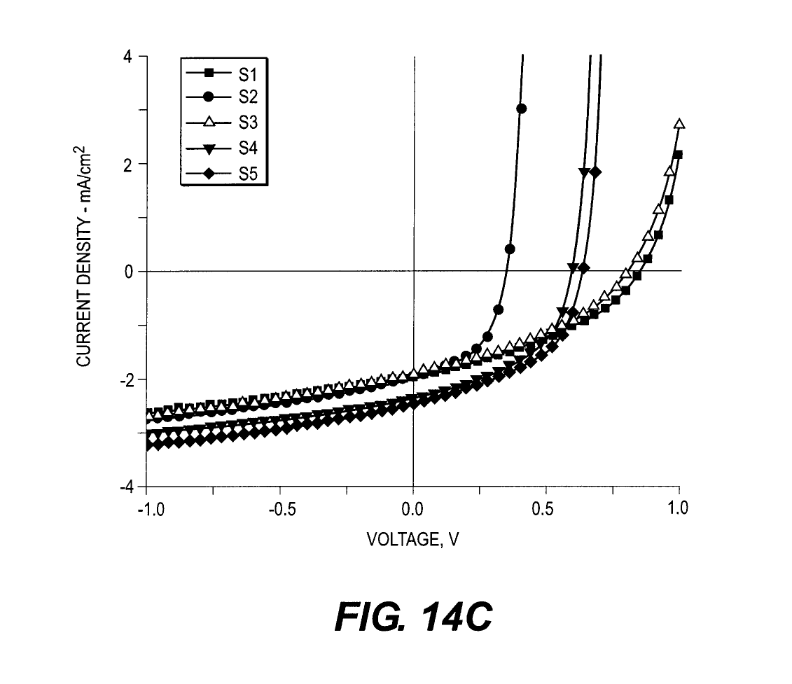

As for macrocyclic compounds, MTPP can be extended to different porphyric monomers, porphyric oligomers, fused and co-fused porphyrins, phthalocyanine derivatives, and other macrocyclic systems as illustrated in FIG. 11. Macrocycles can be expended by size of cycles and/or by replacing N by other hetero-atoms such as O, C, P, S that can coordinate to metal center (FIG. 12). The requirement is that the metal center needs to have open coordination site, i.e. behaves like Lewis acid to react with appropriate ligands (Lewis bases).

The ligands can be any Lewis base that can coordinate to metal center of macrocycles. The Lewis base centers can be C or any elements from main group VI and VII of the periodic table of elements, namely N, P, As, Sb, O, S, Se and Te (FIG. 13). Examples of C based ligands are isonitriles derivatives, noncyclic and cyclic carbenes. Varieties of group VI A and VII A element based ligands are also listed. Note that the condition for chemical annealing can be different from ambient room temperature and atmosphere pressure, for instance temperature might be increased or pressure may be reduced to get adequate ligands' vapor pressure for reaction.

There is disclosed a method for preparing ordered crystalline organic films by chemical annealing, said method comprising:

(a) forming an organic film comprising at least one metal-containing, macrocyclic compound; and

(b) exposing the organic film to a vapor comprising at least one ligand for a time sufficient to coordinate said ligand to metal centers in the metal-containing, macrocyclic compound, thereby forming an ordered crystalline organic film.

In one embodiment, the metal-containing, macrocyclic compound comprises at least one substance chosen from porphyric monomers, porphyric oligomers, fused and co-fused porphyrins, and phthalocyanine derivatives, such as tetraphenyl phorphyrin (TTP).

In one embodiment, the metal-containing, macrocyclic compound comprises Zn or Mg. Therefore, the at least one metal-containing, macrocyclic compound is a metal tetraphenyl porphyrin (MTPP) chosen from Zinc tetraphenyl porphyrin (ZnTPP) and magnesium tetraphenyl porphyrin (MgTPP).

In one embodiment, the at least one ligand comprises a Lewis base, such as C based ligands, group VI based ligands, group VII based ligands, or combinations thereof. The C— based ligands are chosen from isonitrile derivatives, noncyclic and cyclic carbenes.

In one embodiment, the at least one ligand is a N-based ligand chosen from pyridine (py), 4-cyano pyridine (pyCN), 4-dimethylamino pyridine (dmap), triazine, pyrazine (pyz), imidazole (Himi), methyl imidazole (Meimi), phenyl imidazole (Phimi), diethylamine (Et₂N), triethylamine (Et₃N) and tetrahydrofuran (THF).

There is also disclosed a method for preparing an organic photovoltaic device, such as a solar cell, comprising an ordered crystalline organic film, the method comprising:

(a) providing a first electrically conductive layer;

(b) depositing at least one donor material on the first electrically conductive layer, the donor layer comprising an organic film comprising at least one metal-containing, macrocyclic compound;

(c) exposing the organic film to a vapor comprising at least one ligand for a time sufficient to coordinate the ligand to metal centers in the metal-containing, macrocyclic compound, thereby forming an ordered crystalline organic film;

(d) depositing at least one acceptor material on the ordered crystalline organic film; and

(e) depositing a second electrically conductive layer on top of the acceptor material.

The at least one acceptor material that can be used herein may comprise at least one compound chosen from C₆₀, C₇₀, C₈₄, 3,4,9,10-perylenetracarboxylic dianhydride (PTCDA), 3,4,9,10-perylenetracarboxylic diimide (PTCDI), 3,4,9,10-perylenetetracarboxylic-bis-benzimidazole (PTCBI), 1,4,5,8-naphthalenetetracarboxylic dianhydride (NTCDA), copper pthalocyanine (CuPc), and copper-hexadecafluoro-phthalocyanine (F₁₆-CuPc).

The first or second electrically conductive layer may comprise transparent conducting oxides or transparent conducting polymers, such as conducting oxides are chosen from indium tin oxide (ITO), tin oxide (TO), gallium indium tin oxide (GITO), zinc oxide (ZO), and zinc indium tin oxide (ZITO), and the transparent conductive polymers comprise polyanaline (PANI).

In one embodiment, the first or second electrically conductive layer may comprise a metal substitute, a non-metallic material or a metallic material chosen from Ag, Au, Ti, Sn, and Al.

In one embodiment, the device described herein may further comprise at least one exciton blocking layer, such as an exciton blocking layer is chosen from bathocuproine (BCP), bathophenanthroline (BPhen), 3,4,9,10-perylenetetracarboxylicbis-benzimidazole (PTCBI), 1,3,5-tris(N-phenylbenzimidazol-2-yl)benzene (TPBi), tris(acetylacetonato) ruthenium(III) (Ru(acaca)₃), and aluminum(III)phenolate (Alq₂ OPH).

### EXAMPLE

### Materials and Thin Film Preparation

MTPP (M=Zn, Mg), Bathocuproine (BCP), Fullerene (C₆₀) were purified by thermal sublimation before use. Other ligands were used as received. The organic films with varied thicknesses were made by thermal evaporation at pressure 3×10⁻⁶ torr, at the rate 2 Å/s. MTPP films were exposed to vapors of ligand at room temperature (23-30° C.), under N₂ atmosphere for device fabrication or in the air atmosphere for other measurements.

Thin films of MTPP (M=Zn, Mg) were made and chemically annealed with vapors of various ligands shown on scheme 1. Even though reaction of ZnTPP with pyridine derivatives and other Lewis bases as ligands in solution has been previously investigated, there are no examples on reactions of ZnTPP thin film with vapors of these ligands. The coordination of pyridine to MTPP is illustrated on the scheme 2.

Treatment of ZnTPP Film with Ligands

Reaction of ZnTPP thin films with ligands were visually observed. In particular, the color of ZnTPP films turned from pink-red to green spontaneously when exposed to ligands' vapors. In the case of triazine and pyz, the green films further changed to pink-red color within 10 minutes, and no more change in color was observed.

### UV-Vis Measurement

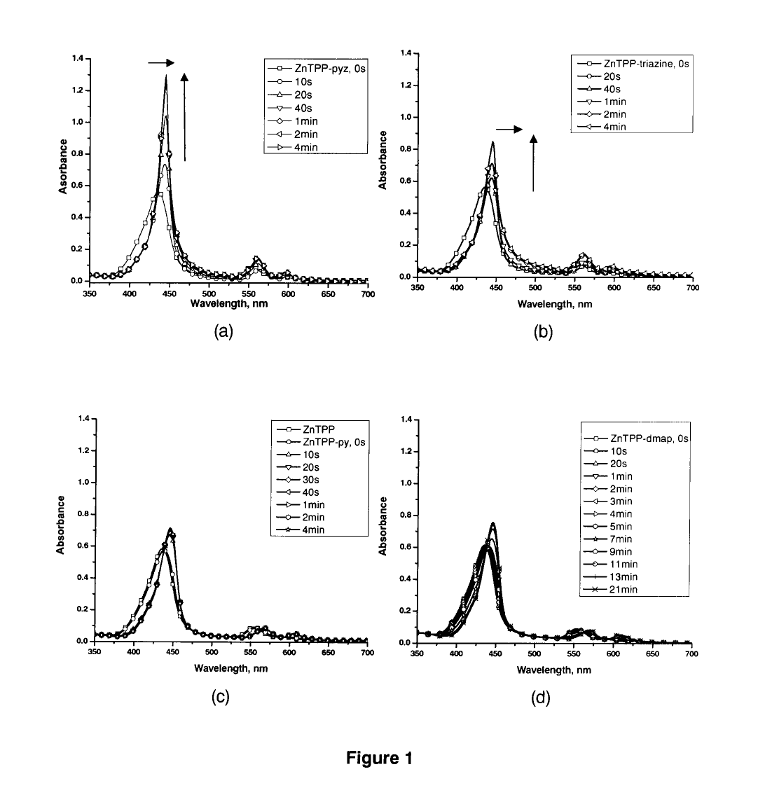

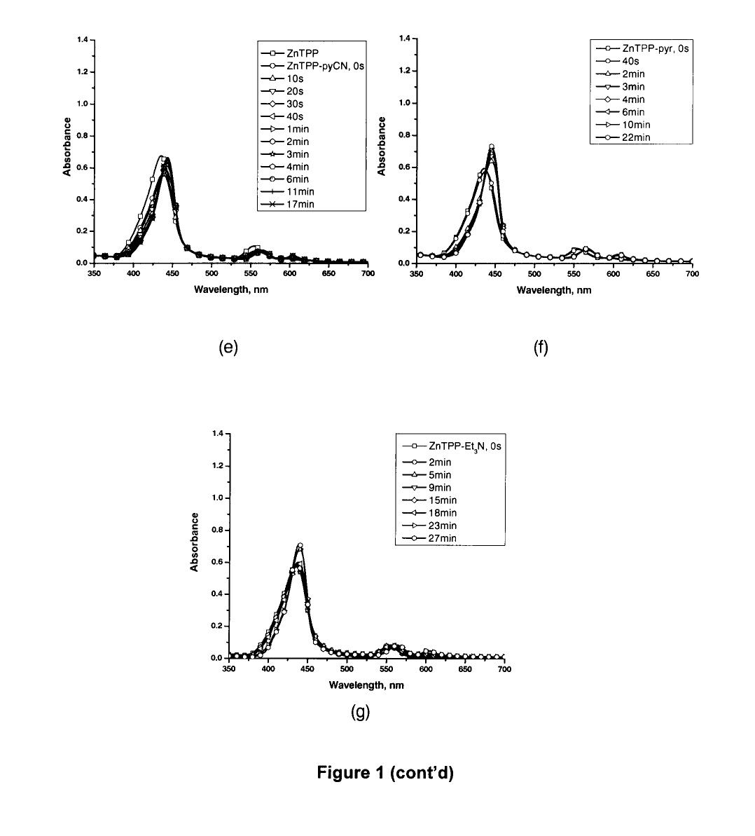

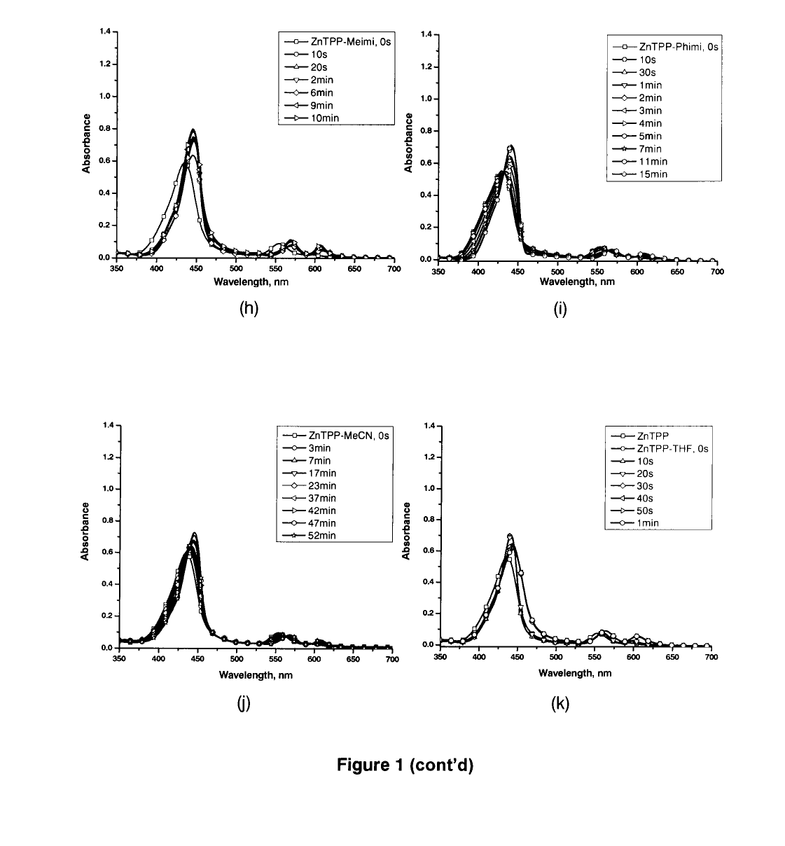

100 Å film of ZnTPP were placed on glass substrate in the cuvette with ligands covered by the cap, and recorded the evolution of UV-vis spectra over time. It was noted that there was no direct contact between ligands and ZnTPP film, and ZnTPP film reacted with vapor of ligands. The UV-vis spectra of MTPP films treated with ligands are shown in FIG. 1.

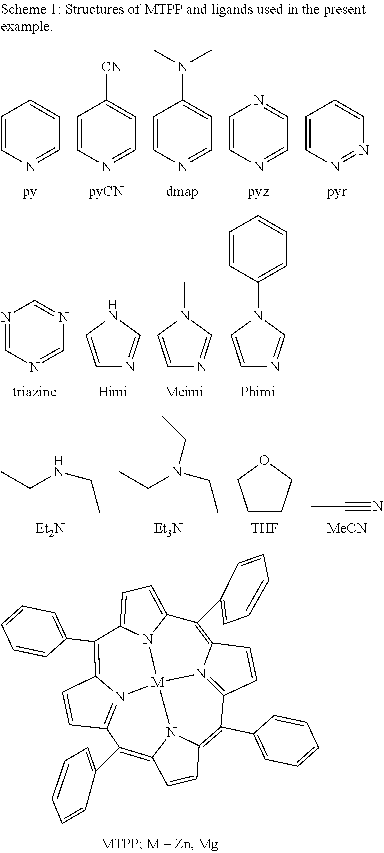

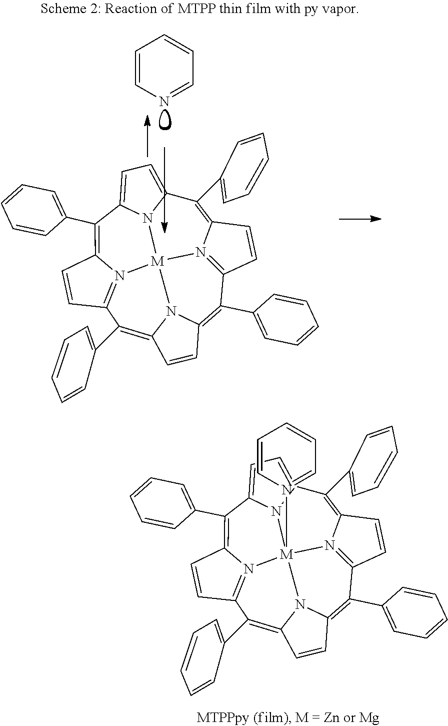

100 Å film of ZnTPP was placed on glass substrate in the cuvette with ligands covered by the cap, and recorded the evolution of UV-vis spectra over time. It was noted that there was no direct contact between ligands and ZnTPP film, and ZnTPP film reacted with vapor of ligands. The UV-vis spectra of MTPP films treated with ligands are shown in FIG. 1.

As ZnTPP reacts with ligands both Soret and Q bands undergo bathochromic shift, which was observed in study of interaction between ZnTPP and ligands in solution. Isosbestic point on the spectrum indicates that ZnTPP reacts with ligand producing only one product ZnTPP.x-ligand (x=1 or 2). The reaction time depends on partial vapor pressure of ligand and binding strength of the ligands to ZnTPP, varying from seconds to minutes. Interestingly, the Soret band sharpens as reaction proceeds, especially when the ZnTPP are treated with pyz and triazine. Peak sharpening is the first sign of structural reorganization of ZnTPP.x ligand film.

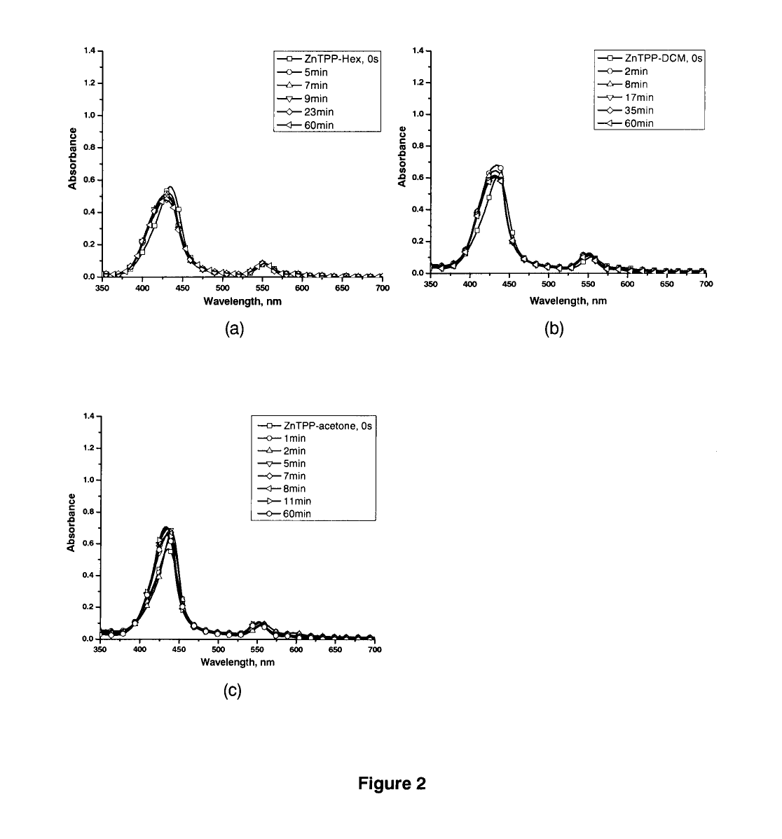

Change in absorption spectra of ZnTPP under solvent vapors varying from noncoordinating and nonpolar Hexanes, to polar Dichloromethane (DCM) and weak coordinating acetone has been investigated for comparison with above coordinating ligands (FIG. 2). Unlike coordinating ligands, noncoordinating solvent vapors just diffuse into the film, increasing mobility of ZnTPP molecules, thus result in broadening features of spectra.

### Film Composition

To identify the composition of the film after exposure to ligands ZnTPP.x ligand, the following experiment was set up: 1500 Å films of ZnTPP was deposited on clean glass substrates, then treated with pyz or triazine for 3 hours to make sure the reactions accomplished. The films were then placed under high vacuum (3×10⁻⁶ torr) for one hour to remove excess of ligands (if any) weakly bound to the film surfaces. After that, ZnTPP.x-ligand was rinsed off from glass substrates using D-chloroform to record ¹H and ¹³C NMR spectra.

ZnTPP.x pyz: ¹H NMR (400 MHz, CDCl₃): δ 7.023 (broaden peak, 4H, pyz), 7.705-7.785 (m, 12H, ZnTPP), 8.175-8.198 (m, 8H, ZnTPP), 8.896 (s, 8H, ZnTPP). ¹³C NMR (400 MHz, CDCl₃): δ 120.871, 126.431, 127.362, 131.837, 134.462, 143.001, 143.376, 150.058. Based on peak integration, number of pyz ligand x=1.

ZnTPP.x triazine: ¹H NMR (400 MHz, CDCl₃): δ 7.718-7.795 (m, 12H, ZnTPP), 8.112 (broaden peak, 3H, triazine), 8.204-8.227 (m, 8H, ZnTPP), 8.933 (s, 8H, ZnTPP). ¹³C NMR (400 MHz, CDCl₃): δ 121.045, 126.503, 127.448, 131.444, 142.857, 150.150, 164.936. Number of triazine ligand x=1. Thus, the composition of the film is ZnTPP:ligand=1:1.

AFM Images of ZnTPP Film Treated with Ligands

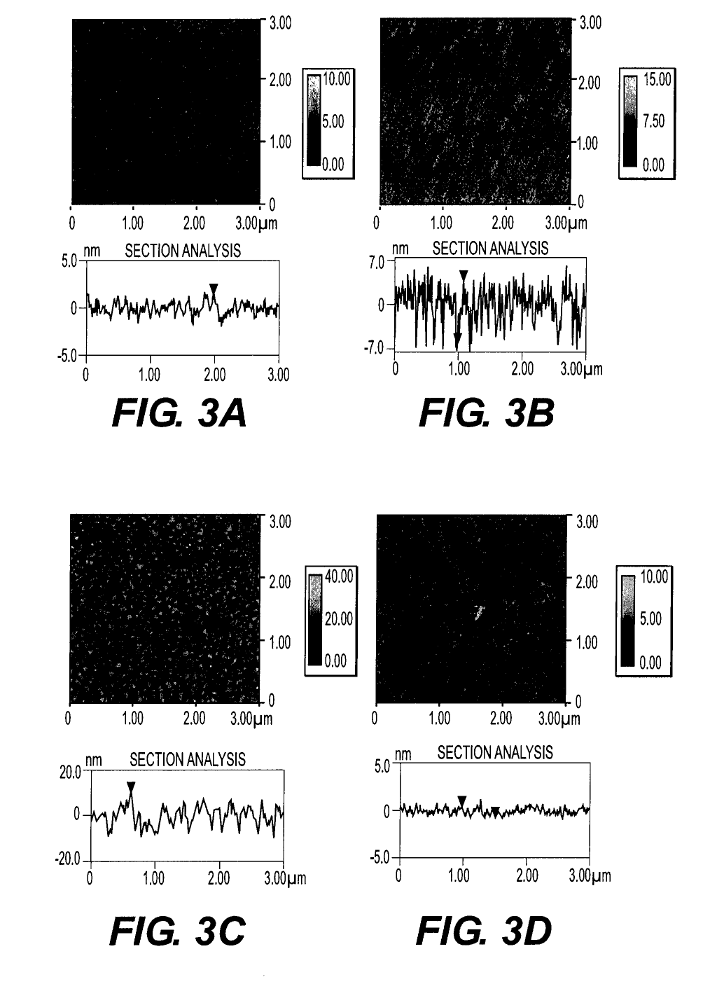

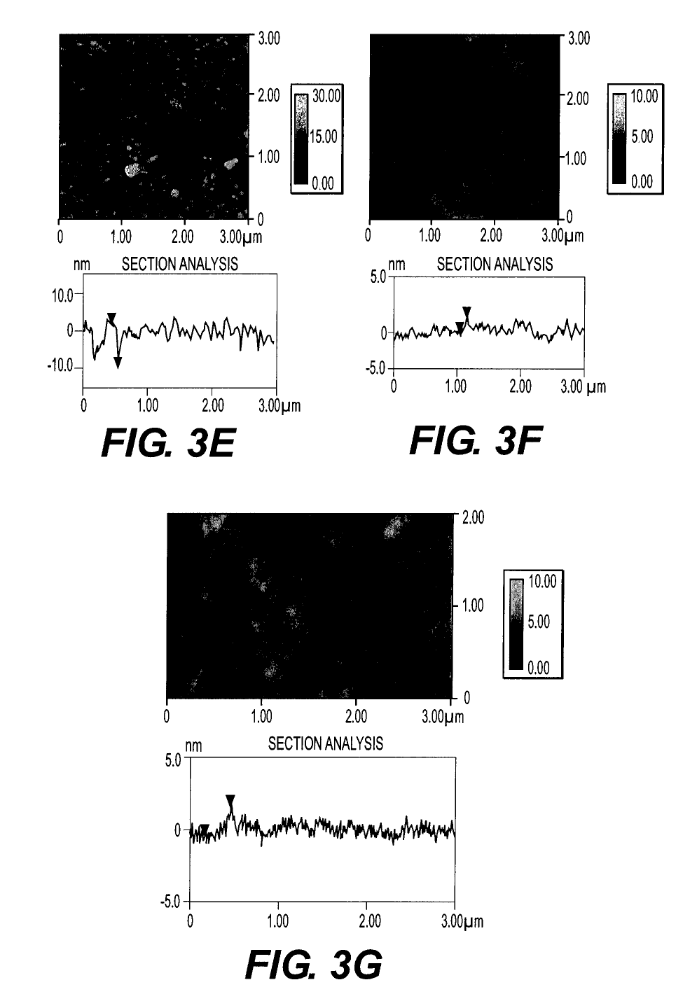

AFM topological images of 100 Å film of ZnTPP on the glass substrates before and after chemical annealing with different ligands are shown in FIG. 3. The ZnTPP film is quite uniform with small rms value. The roughness of the film increases as ZnTPP reacts with ligands, and grains are formed with the size increasing overtime. In the case of ligands which have high vapor pressure at room temperature, such as py, pyr, Et₂NH, Et₃N and THF, the change in roughness of the films can be visually observed after 3-5 minutes exposure to ligands vapors. After 3-4 hours exposure of the ZnTPP film to those ligands results in condensation of ligands on the surface of substrate.

### X-ray Diffraction (XRD) Measurement

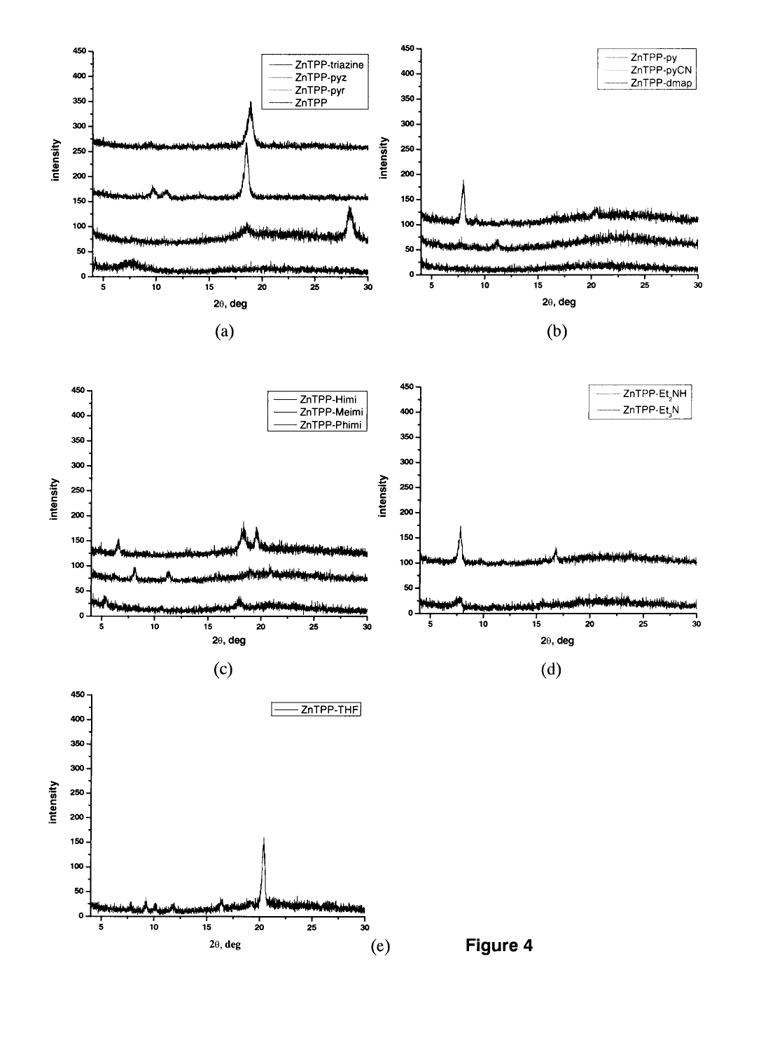

Further change in film morphology has been studied by XRD measurement. 1000 \acute{Å} ZnTPP films were deposited on glass substrates, and the diffraction patterns (FIG. 4) were measured by grazing incidence diffraction method. The initial ZnTPP film is amorphous with very weak and broaden diffraction peak at 2θ=6°. After chemical annealing with different ligands, the films become polycrystalline with diffraction patterns appear at various 2θ angles and have different intensities depending on substituent groups of ligands and their vapor pressures.

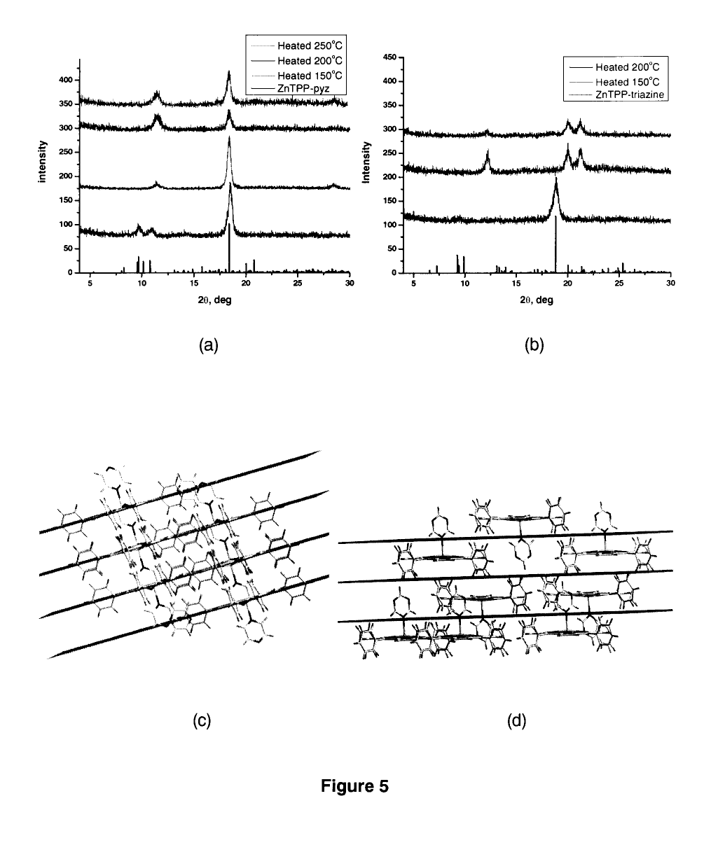

Attempt to define the organized structure of chemically treated films has been realized by comparing simulated diffraction patterns from single crystals ZnTPP.triazine and ZnTPP.pyz with corresponding films (FIG. 5). The peaks at 2θ=18.5° (ZnTPP.pyz film) and 18.8° (ZnTPP.triazine) were positively identified as X-ray diffraction from planes, which have the same distance between macrocycles and are parallel to them. Thus, reorganization of film structure to highly ordered film with stacked parallel macrocycles result in significant change in the shape of UV-vis spectra of ZnTPP.pyz and ZnTPP.triazine as mentioned above. Interestingly, upon removal of pyz from the film by heating the peak at 18.5° remains unchanged, while removing triazine from ZnTPP.triazine results in significant change in diffraction patterns (complete removal pyz and triazine at 250° C. was confirmed by NMR and thermal gravimetric analysis). Pyz and triazine can reversely bind to thermally treated films.

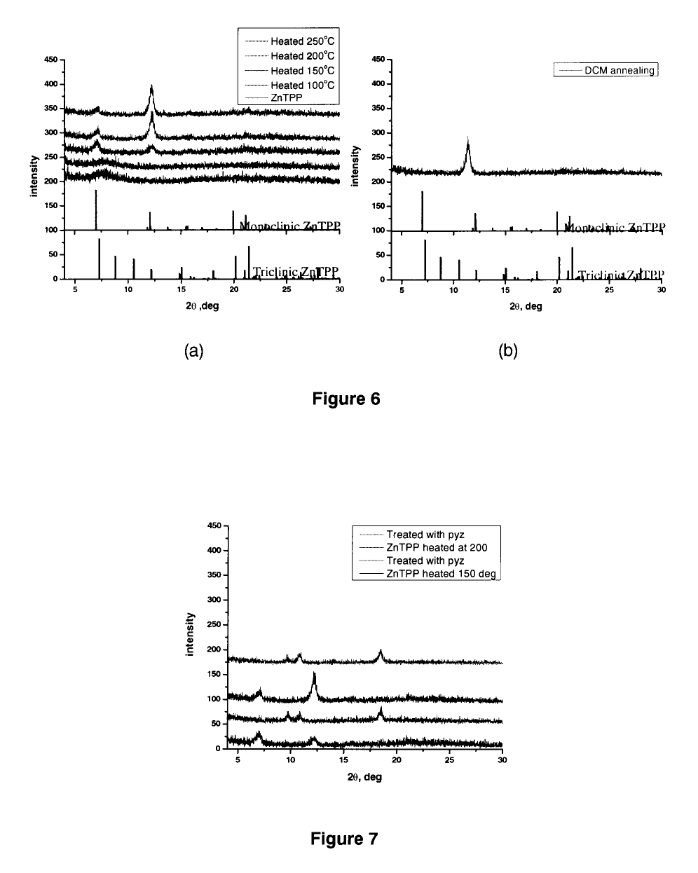

To compare physical and chemical methods, the ZnTPP films have been subject to thermal and solvent (dichloromethane, DCM) annealing (FIG. 6). Thermal treatment requires relatively high temperature to form ordered film (150° C.). XRD patterns of thermal and solvent annealed films show peaks at 2θ=12.2° and 11.3°, respectively. When thermally annealed films are treated with pyz, they give same diffraction pattern as the initial ZnTPP films are treated with pyz (FIG. 7).

### Fabrication of Organic Photovoltaics (OPV) Devices

OPV devices using ZnTPP, and pyz, triazine treated ZnTPP films as donor layers were chosen to study the effect of chemical annealing on device performance. Lamellar OPV devices were fabricated as the following procedure: ZnTPP films were deposited onto pre-cleaned ITO coated glass substrates with the rate 2 \acute{Å}/s. Since Oxygen affects badly on device performance, all chemical treatment of ZnTPP films with ligands was done under Nitrogen atmosphere at room temperature (26-30° C.). After that, 400 \acute{Å} of C₆₀, 100 \acute{Å} of BCP and 1000 \acute{Å} of Al were subsequently deposited.

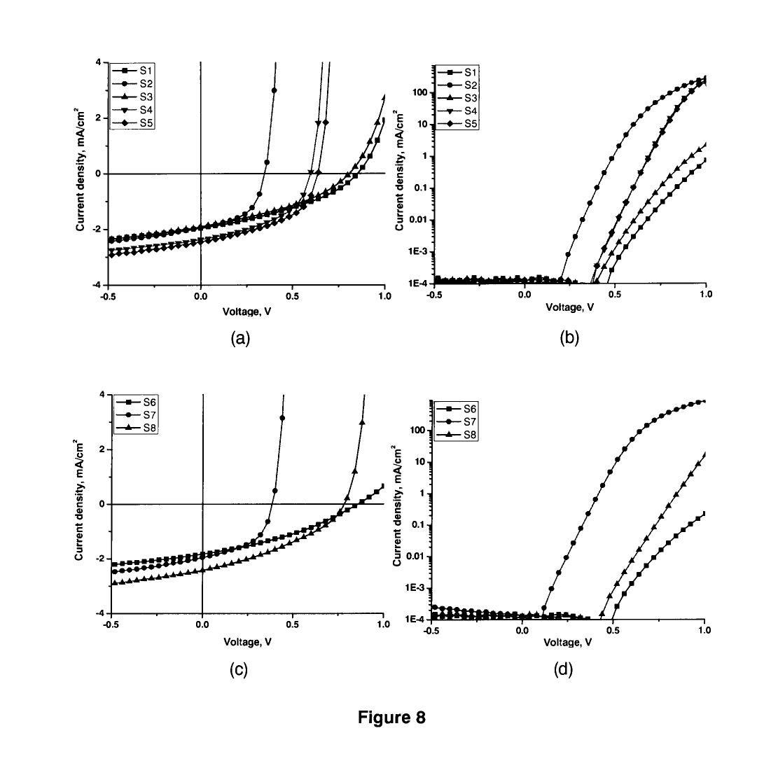

J-V curves of OPV devices under the dark and illumination conditions are shown in FIG. 8, and some data of representative devices are presented in Table 1. Performance of devices which have the same thickness of donor materials—150 \acute{Å} (S1-5) and 200 \acute{Å} (S6-8)—were also compared.

Chemical treatment of ZnTPP with pyz results in lower V_{OC}, higher conductivity and higher dark current Jₛ as compared with devices using ZnTPP as donor layer (S2 vs. S1, and S7 vs. S6). The reverse relationship between Jₛ and V_{OC} have been well established. Highly ordered crystalline film ZnTPP.pyz conducts holes (positive charges) better than amorphous ZnTPP film, thus results in low series resistance Rₛ and good FF (Table 1).

Table 1 shows dark and light characteristic parameters of devices: ITO/donor layer/C₆₀ (400 \acute{Å})/BCP (100 \acute{Å})/Al (1000 \acute{Å}), the donor layers were treated in different ways: S1—ZnTPP (150 \acute{Å}), S2—ZnTPP (150 \acute{Å})-pyz, S3—NPD (100 \acute{Å})/ZnTPP (150 \acute{Å})-pyz, S4—NPD (100 \acute{Å})/ZnTPP (150 \acute{Å})-pyz, S5—ZnTPP (100 \acute{Å})-pyz/ZnTPP (50 \acute{Å}), S6—ZnTPP (200 \acute{Å}), S7—ZnTPP (200 \acute{Å})-pyz and S8—ZnTPP (100 \acute{Å})-pyz/ZnTPP (100 \acute{Å}).

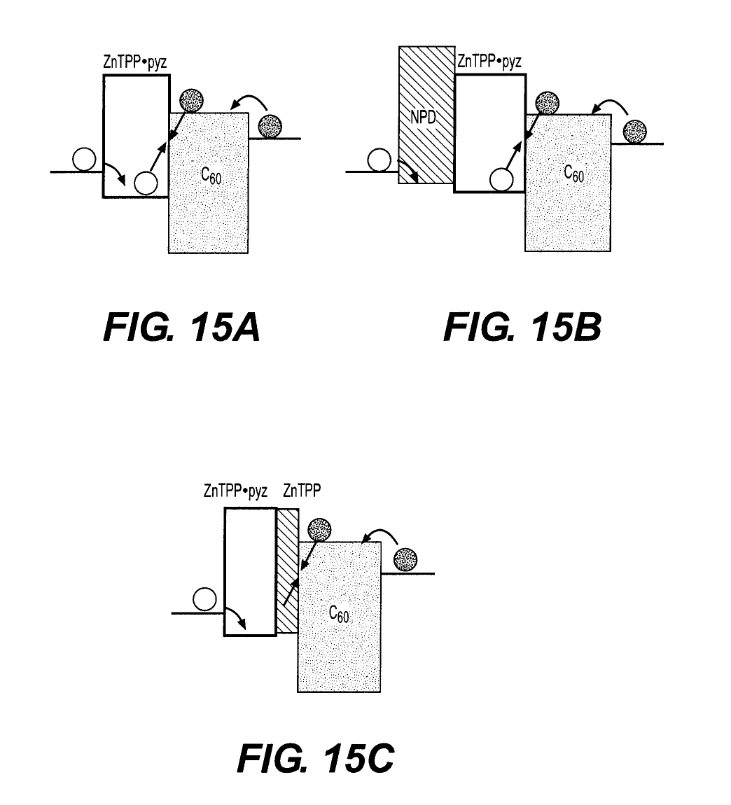

On the other hand, highly conductive donor layer ZnTPP.pyz might lead to high concentration of holes near Donor/Acceptor interface which cause large recombination under dark condition (scheme 1-a). In order to decrease Jₛ to get back V_{OC} an amorphous layer next to the ZnTPP.pyz layer was introduced to providing that it still allow sufficient hole extraction process. When a 100 \acute{Å} layer of N,N′-Di-[(1-naphthyl)-N,N′-diphenyl]-1,1′-biphenyl)-4,4′-diamine (NPD) is placed onto ITO, performance of OPV using ZnTPP as donor layer does not change (S3 vs. S1). However, insertion of 100 \acute{Å} NPD beneath (device S4, FIG. 15(b) or 50 \acute{Å} of ZnTPP above (device S5, FIG. 15(c) ZnTPP.pyz significantly reduces Jₛ, and increases both V_{OC} and J_{SC} while maintaining good FF of devices with donor layer treated with pyz.

The device with thicker film of ZnTPP (100 \acute{Å}) on top of ZnTPP.pyz have comparable V_{OC} and higher J_{SC} than device with untreated ZnTPP donor layer.

TABLE 1

| | J_{sc} | | | | | Jₛ 10⁻⁶ | Rₛ 10⁻⁵ |
|---|---|---|---|---|---|---|---|
| Devices | (mA/cm²) | V_{oc} (V) | FF | η (%) | n | (mA/cm²) | (Ωcm²) |
| S1 | 1.96 | 0.853 | 0.37 | 0.616 | 2.1 | 0.08 | 13.9 |
| S2 | 1.95 | 0.346 | 0.52 | 0.349 | 1.5 | 5.1 | 0.1 |
| S3 | 1.91 | 0.808 | 0.37 | 0.573 | 2.1 | 0.3 | 4.8 |
| S4 | 2.36 | 0.598 | 0.47 | 0.665 | 1.4 | 0.01 | 0.06 |
| S5 | 2.45 | 0.638 | 0.48 | 0.745 | 1.4 | 0.02 | 0.05 |
| S6 | 1.82 | 0.856 | 0.35 | 0.544 | 2.6 | 0.5 | 7.8 |
| S7 | 1.95 | 0.383 | 0.51 | 0.379 | 1.5 | 0.05 | 0.04 |
| S8 | 2.42 | 0.782 | 0.36 | 0.690 | 1.8 | 0.06 | 0.2 |

Treatment of MgTPP with Ligands

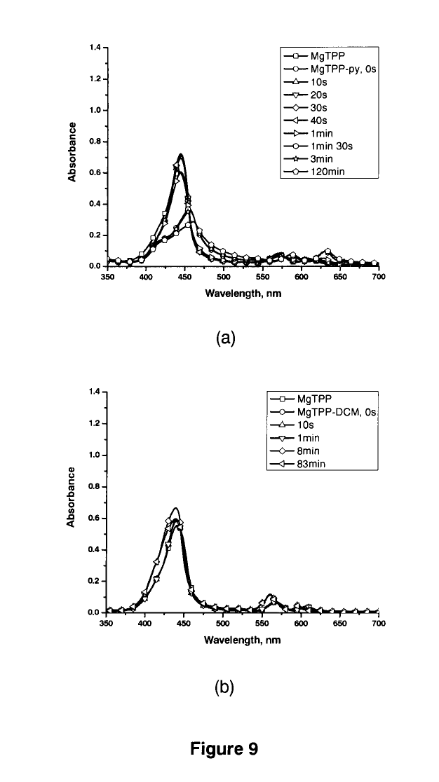

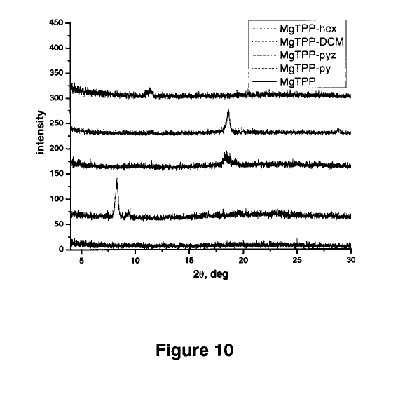

Reactions of MgTPP film with py and pyz also have been studied with UV-vis absorption and XRD measurements (FIGS. 9 and 10). Quite complicated change in UV-vis spectra when MgTPP film is treated with py or pyz might due to the fact that one or two ligand molecules can coordinate to one Mg atom. Upon chemical annealing, MgTPP film undergoes morphology change from amorphous to polycrystalline.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for preparing ordered crystalline organic films by chemical annealing, said method comprising:
(a) forming an organic film comprising at least one metal-containing, macrocyclic compound; and
(b) exposing said organic film to a vapor comprising at least one ligand for a time sufficient to coordinate said ligand to metal centers in said metal-containing, macrocyclic compound, thereby forming an ordered crystalline organic film.

2. The method according to claim 1, wherein said at least one metal-containing, macrocyclic compound comprises at least one substance chosen from porphyric monomers, porphyric oligomers, fused and co-fused porphyrins, and phthalocyanine derivatives.

3. The method according to claim 2, wherein said at least one metal-containing, macrocyclic compound comprises a porphyric monomer chosen from tetraphenyl phorphyrin (TTP).

4. The method according to claim 1, wherein said metal-containing, macrocyclic compound comprises Zn or Mg.

5. The method according to claim 4, wherein said at least one metal-containing, macrocyclic compound is a metal tetraphenyl porphyrin (MTPP) chosen from Zinc tetraphenyl porphyrin (ZnTPP) and magnesium tetraphenyl porphyrin (MgTPP).

6. The method according to claim 1, wherein said at least one ligand comprises a Lewis base.

7. The method of claim 6, wherein said Lewis base comprises C based ligands, group VI based ligands, group VII based ligands, or combinations thereof.

8. The method according to claim 7, wherein said C-based ligands are chosen from isonitrile derivatives, noncyclic and cyclic carbenes.

9. The method according to claim 1, wherein said at least one ligand is a N-based ligand chosen from pyridine (py), 4-cyano pyridine (pyCN), 4-dimethylamino pyridine (dmap), triazine, pyrazine (pyz), imidazole (Himi), methyl imidazole (Meimi), phenyl imidazole (Phimi), diethylamine (Et₂N), triethylamine (Et₃N) and tetrahydrofuran (THF).

10. The method according to claim 1, wherein said forming comprises thermal evaporation.

11. The method according to claim 1, wherein said exposing was conducted in an inert atmosphere at a temperature ranging from 20° C. to 50° C.

12. The method according to claim 11, wherein said inert atmosphere comprises nitrogen.

13. A method for preparing an organic photovoltaic device comprising an ordered crystalline organic film, said method comprising:
(a) providing a first electrically conductive layer;
(b) depositing at least one donor material on said first electrically conductive layer, said donor layer comprising an organic film comprising at least one metal-containing, macrocyclic compound;
(c) exposing said organic film to a vapor comprising at least one ligand for a time sufficient to coordinate said ligand to metal centers in said metal-containing, macrocyclic compound, thereby forming an ordered crystalline organic film;
(d) depositing at least one acceptor material on said ordered crystalline organic film; and
(e) depositing a second electrically conductive layer on top of said acceptor material.

14. The method according to claim 13, wherein the at least one acceptor material comprises at least one compound chosen from C₆₀, C₇₀, C₈₄, 3,4,9,10-perylenetracarboxylic dianhydride (PTCDA), 3,4,9,10-perylenetracarboxylic diimide (PTCDI), 3,4,9,10-perylenetetracarboxylic-bis-benzimidazole (PTCBI), 1,4,5,8-naphthalenetetracarboxylic dianhydride (NTCDA), copper pthalocyanine (CuPc), and copper-hexadecafluoro-phthalocyanine (F₁₆-CuPc).

15. The method of according to claim 13, wherein said first or second electrically conductive layer comprises transparent conducting oxides or transparent conducting polymers.

16. The method of according to claim 14, wherein the conducting oxides are chosen from indium tin oxide (ITO), tin oxide (TO), gallium indium tin oxide (GITO), zinc oxide (ZO), and zinc indium tin oxide (ZITO), and the transparent conductive polymers comprise polyanaline (PANI).

17. The method of according to claim 13, wherein said first or second electrically conductive layer comprises a metal substitute, a non-metallic material or a metallic material chosen from Ag, Au, Ti, Sn, and Al.

18. The method of claim 13, further comprising at least one exciton blocking layer.

19. The method of claim 18, wherein said exciton blocking layer is chosen from bathocuproine (BCP), bathophenanthroline (BPhen), 3,4,9,10-perylenetetracarboxylicbis-benzimidazole (PTCBI), 1,3,5-tris(N-phenylbenzimidazol-2-yl)benzene (TPBi), tris(acetylacetonato) ruthenium(III) (Ru(acaca)₃), and aluminum(III)phenolate (Alq₂ OPH).

20. The method of claim 13, wherein the organic photovoltaic device comprises a solar cell.

21. The method according to claim 13, wherein said at least one macrocyclic comprises at least one substance chosen from porphyric monomers, porphyric oligomers, fused and co-fused porphyrins, and phthalocyanine derivatives.

22. The method according to claim 21, wherein said at least one macrocyclic comprises a porphyric monomer chosen from tetraphenyl phorphyrin (TTP).

23. The method according to claim 13, wherein said metal-containing, macrocyclic compound comprises Zn or Mg.

24. The method according to claim 23, wherein said at least one metal-containing, macrocyclic compound is a metal tetraphenyl porphyrin (MTPP) chosen from Zinc tetraphenyl porphyrin (ZnTPP) and magnesium tetraphenyl porphyrin (MgTPP).

25. The method according to claim 13, wherein said at least one ligand comprises a Lewis base.

26. The method of claim 25, wherein said Lewis base comprises C based ligands, group VI based ligands, group VII based ligands, or combinations thereof.

27. The method according to claim 26, wherein said C-based ligands are chosen from isonitrile derivatives, noncyclic and cyclic carbenes.

28. The method according to claim 26, wherein said at least one ligand is a N-based ligand chosen from pyridine (py), 4-cyano pyridine (pyCN), 4-dimethylamino pyridine (dmap), triazine, pyrazine (pyz), imidazole (Himi), methyl imidazole (Meimi), phenyl imidazole (Phimi), diethylamine (Et₂N), triethylamine (Et₃N) and tetrahydrofuran (THF).

29. The method according to claim 13, wherein said forming comprises thermal evaporation.

30. The method according to claim 13, wherein said exposing was conducted in an inert atmosphere at a temperature ranging from 20° C. to 50° C.

31. The method according to claim 30, wherein said inert atmosphere comprises nitrogen.
